(19) United States
(12) Patent Application Publication
(10) Pub. No.: US 2026/0218041 A1
(43) Pub. Date: Jul. 30, 2026

(54) AMINE-FREE METHOD OF HIGH-QUALITY SILICA GROWTH FOR QD ENCAPSULATION

(71) Applicant: ams-OSRAM International GmbH, Regensburg (DE)

(72) Inventors: Kira HUGHES LUND, Tigard, OR (US); Benjamin MANGUM, Tualatin, OR (US)

(21) Appl. No.: 19/147,646

(22) PCT Filed: Jan. 10, 2024
(86) PCT No.: PCT/EP2024/050510

§ 371 Date: Jul. 11, 2025

Related U.S. Application Data
(60) Provisional application No. 63/479,826, filed on Jan. 13, 2023.

(51) Int. Cl. C09K 11/02; B82Y 30/00; B82Y 40/00; H10K 50/115

(52) U.S. Cl. CPC C09K 11/025; B82Y 30/00; B82Y 40/00; H10K 50/115

(57) ABSTRACT

The present disclosure concerns an improved method for the production of silica encapsulated quantum dots with improved photoluminescence quantum yield at elevated temperatures. The disclosure further concerns quantum dots prepared by the novel process and the application of the quantum dots in an optoelectronic device.

The present application claims priority from application no. U.S. 63/479,826 dated Jan. 13, 2023, the disclosure of which is incorporated herein by reference in its entirety.

The present invention concerns an improved method for the production of silica encapsulated quantum dots with improved photoluminescence quantum yield at high stress conditions including elevated temperatures, high excitation flux, and exposure to ambient conditions including oxygen and moisture. The invention further concerns quantum dots prepared by the novel process and the application of the quantum dots in an optoelectronic device.

### BACKGROUND

Quantum dots are semiconductor particles a few nanometres in size up to about 10 nm, having optical and electronic properties that differ from those of larger particles as a result of quantum mechanics. When quantum dots based on semiconductor materials are illuminated by a primary light source, an electron from the valence band is excited to a state of higher energy in the conduction band. The excited electron can drop back into the valence band releasing its energy as light. The colour of that light depends on the energy difference between the conduction band and the valence band, which is largely based on the material properties of the quantum dot as well as its dimensions.

Quantum dots can be used for a variety of applications, some of which refer to down-shifting or down-converting of light, respectively, in order to mix primary light with down-converted light for example. In such applications, quantum dots absorb light of a particular first (available or selected) wavelength, usually blue, and then emit light at a second wavelength, usually red or green. Other potential applications for quantum dots include single-electron transistors, solar cells, LEDs, lasers, [8] single-photon sources, second-harmonic generation, quantum computing, cell biology research, microscopy, and medical imaging.

Quantum dots often, but not necessarily, are comprised of the primary material known as the core or seed, and are subsequently coated in other semiconductor shell layers. Such shell layers may be comprised of distinct semiconductor materials from the core. Common core-shell quantum dot systems include CdSe cores, with shells of CdS and/or ZnS surrounding the core. Such shell layers may be beneficial for absorption, and or emission purposes. When semiconductor shell layers are used, they may introduce some challenges, such as introducing strain from lattice mismatches between the different types of semiconductor crystals present in the overall structure. Optimization of shell material and thickness is done in conjunction with core size, shape and composition to achieve the desired optical and/or electronic properties. For the present application, the term quantum dot shall refer to both simple core-only quantum dot structures as well as cores with single or multiple semiconductor shell layers.

Quantum dots are characterised by their respective photoluminescence quantum yield (PLQY). The PLQY of a molecule or material including quantum dots is defined as the number of photons emitted as a fraction of the number of photons absorbed. Several parameters can influence the PLQY of quantum dots including, but not limited to the temperature during its generation, the encapsulating material if any, any material attached to the surface of the quantum dots and so forth.

Optimizing the PLOY of quantum dots and improving the long-time stability to be less prone to environmental changes is therefore desirable for a variety of applications.

### SUMMARY OF THE INVENTION

This and other objects are addressed by the subject matter of the independent claims. Features and further aspects of the proposed principles are outlined in the dependent claims.

The low PLQY of prior art quantum dots, often under high stress conditions, is also attributed to a poor nanocrystalline surface and crystalline quality. The poor quality may result from a previous lack of capability in synthetic techniques for treating or tailoring the nanocrystal surface in order to achieve PLOYs above 90 percent. For example, the surface may have a large number of dangling bonds which act as trap states to reduce emission and, hence, the PLQY.

To improve the situation, Quantum dots are usually encapsulated in another material, very often silica or SiO2 due to its transparency in the interesting light spectrum. The encapsulation also serves as a protection for the quantum dots from oxidation, decomposition or other environmental influences and may also generate a higher temperature stability.

In an effort to stabilize QDS against the damaging impact of its local environment, silica shell layers have been added to surround QD materials. While silica shell growth can be either acid or base catalysed, most favourable results are achieved via base-catalysed silica growth. For such base catalysed reactions, NH3 (aq.) has been used as catalyst to achieve uniform silica growth, also because any syntheses without NH3 is limited (aq.) and time-consuming. Additionally, in syntheses without (3-Amino-propyl)trimethoxysilane (APTMS) as additional reactant, the silica first grows at the ends of elongated quantum dots (QDs). As the silica grows, it eventually connects along the side, but results in small voids along the side of the quantum dots heterostructure from incomplete growth around the entirety of the particle, in cases, in which no linker like APTMS is used.

To overcome this issue, the inventors propose a new method for growing high-quality silica encapsulation spheres on quantum dots without the use of either amine. It has been triggered by the observation that the PLQY of silica-encapsulated quantum dots is decreasing due to mixing of quantum dots with NH3 (aq.) prior to encapsulation.

The inventors now propose to use LiOH (aq.) to catalyse the conversion of silica precursors such as TEOS to silica. It has been surprisingly observed that silica shells can be grown encapsulating the quantum dots heterostructures smoothly and uniformly without the use of APTMS. By changing the concentration of the LiOH (aq) the growth speed and the amount of silica encapsulating the quantum dots can be controlled. Moreover, the above-mentioned voids are prevented leaving significant less free dangling bonds at the surface of the quantum dots thereby improving the PLQY.

The term “shells” here refers to only silica-based shells. They are not equivalent to semiconductor shells, and this invention does not address the use of conformally-grown semiconductor shells. The goal of an amine-free approach for the silica encapsulation is to remove the amine from the equation because it is believed that there might be negative interactions for the QD surface when it is used.

According to a first aspect of the invention, a method for the production of a luminescent material based on silica encapsulated quantum dots is provided. The method comprises the steps of:
a. Providing luminescent quantum dots in a liquid medium,
b. Adding Tetraethyl orthosilicate (TEOS) or Tetramethyl orthosilicate (TMOS) and a hydroxyl base or methoxide base to the liquid medium,
c. Growing silica on the quantum dots, thereby obtaining silica encapsulated quantum dots.

Quantum dots applicable for the proposed method can be selected from various semiconductor materials including Group II-VI materials, Group III-V materials, Group IV-VI materials, Group I-III-VI materials, or Group II-IV-VI materials. Typical material may include GaAs, AlGaAs, InGaN, InGaP, AlGaN, AlGaP, InGaAlP, InGaAlN and CIS (copper indium sulphide) with various stoichiometric settings.

The quantum dots may comprise in some instances an elongated shape with a length between 5 nm and 25 nm and a width of about 3 nm to 10 nm. In some other instances, they have the shape of a cube with an edge length between 5 nm and 20 nm.

In some instances, the step of growing the silica on the quantum dots is based on growing time, temperature and concentration of the added hydroxyl base or methoxide base. A larger concentration will lead not only to a faster growth resulting in a ticker shell for a dedicated growth time.

In some instances, the growth will be interrupted, when the encapsulated quantum dots reach an average size in the range between 20 nm and 35 nm. In some instances, the growth distribution comprises a standard deviation of less than 10 μm and in particular less than 5 μm, and even more particular less than 2 μm of the resulting encapsulated quantum dots. This uniform distribution is useful, as it will simplify further processing with less disadvantageous effect.

The hydroxyl base is an alkali metal hydroxide or earth alkali metal hydroxide or a metal hydroxide from transition metals in some instances. More particularly, the hydroxyl base may be selected from the group consisting of LiOH, NaOH, KOH, RbOH, CsOH, Mg(OH)₂, Ca(OH)₂, Sr(OH)₂, Ba(OH)₂ or Zn(OH)₂, or mixtures thereof.

As an alternative, alkali methoxide (alkali methanolates) bases can be used. The methoxide base is preferably selected from Lithium methoxide, Natrium methoxide, Kalium methoxide, or mixtures thereof.

The liquid medium to which the TEOS and the hydroxyl base or methoxide base is added is selected from water, methanol, or ethanol. Mixtures for those components can be used as a liquid.

In order to achieve the target of the invention, the concentration of the added hydroxyl base or methoxide base is ≥0.05 Mol. It has been found that larger concentrations will result in a faster growth and based on a fixed growth time a thicker shell encapsulating the quantum dots. In some instances the added concentration shall be within the range of 0.05 Mol to 3.0 Mol. Consequently, in some instances, a concentration larger than 0.5 Mol (which corresponds to a concentration of 0.025 M of the base in the total reaction volume) and particularly larger than 0.75 Mol and less than 3.0 Mol. In some instances the concentration is set between 1.5 Mol and 2.5 Mol with regards to the added base.

Silica shells that are grown using with a concentration of added [LiOH]≥0.5 Mol result in improved performance in temperature-dependence experiments over samples synthesized via the standard procedure, with NH3.

A main advantage of the invention is that the reaction of the silica growth can be performed without the use of Ammonia and (3-Aminopropyl)trimethoxysilane (APTMS) as reactants. Thus in some instances, the method according to the invention is free of Ammonia and (3-Aminopropyl)trimethoxysilane (APTMS) as reactants.

However, also a combination of a hydroxyl base and ammonia can be used. While the above invention describes a completely amine-free route to obtain fully silica-encapsulated QD heterostructures, some combination of LiOH (aq.) and NH3 (aq.) (or any combination of two bases mentioned so far) could also be used to obtain an improved encapsulation of the quantum dots.

In some instances, the step of adding hydroxyl base or methoxide base to the liquid medium may comprise in some instances adding hydroxyl base or methoxide base and NH3 together. More particular a mixture of reagents such as (LiOH)1−x(NH3)x (aq.), where 0<x≤1, can be used in some instances. Second, for a multi-step reaction, a combination of LiOH (aq.) and NH3 (aq.) could be used. LiOH (aq.) can be added to the reaction to catalyse the first silica growth step, followed by an additional silica growth step where NH3 (aq.) is used as the catalyst. For multiple subsequent silica growth steps, any combination of orders of the two reagents can be used to obtain large silica-QD particles.

That is, according to a further embodiment of the invention, a combination an Alkali hydroxyl base, earth alkali hydroxyl or hydroxyl base of a transition metal can be applied here. In some instances the growth process is initiated by providing hydroxyl base or methoxide base mixed with TEOS in the liquid medium. Some time after the growth process is started, NH3 (aq.) is added to the mixture.

In such aspects using ammonia is used for the second and, if wanted, for further growth steps. In that regard an overall mixture of M(OH)n (aq.) and NH3 (aq.) can be used with the general distribution of (M(OH)n)1−x((NH3)x (aq,), wherein n=1 or 2, 0≤x≤1 and M is Li, Na, K, Rb, Cs for n=1 and Mg, Ca, Sr, Ba or Zn for n=2. The various components can be added subsequently during the process or together in a single step.

As stated above, in order to generate thicker silica shells, step c. can be repeated one or more times, preferably more than two times, more preferably more than three times. Each step can last for a specific time period after which the growth is interrupted, or further material added. For the additional growth steps it is possible in some instances using the combination of hydroxyl base and ammonia as stated above. The additional growth steps can also be performed without the use of ammonia.

The above-described method provides silica encapsulated quantum dots.

Another aspect of the invention are therefore silica encapsulated quantum dots prepared by the method as described herein.

A further aspect of this invention is an optoelectronic device comprising the silica encapsulated quantum dots prepared by the method disclosed herein. Optoelectronic devices may be LED's, down converters, laser applications and the like. Since the method as described above can be performed in aqueous media, even biological or medical tracer applications are possible for the encapsulated quantum dots of the invention.

According to another aspect of the invention, silica encapsulated quantum dots prepared by the method as described herein are provided.

According to a further aspect of the invention, an optoelectronic device comprising the silica encapsulated quantum dots as described herein is provided.

### SHORT DESCRIPTION OF THE DRAWINGS

Further aspects and embodiments in accordance with the proposed principle will become apparent in relation to the various embodiments and examples described in detail in connection with the accompanying drawings in which

FIG. 1 illustrates an embodiment in accordance with some aspects of the proposed principle;

FIGS. 2A to 2D show a diagram of the growth of the silica shell under varying concentrations of added LiOH;

FIG. 3 shows PLOY data as a function of temperature for films made from the LiOH samples shown in the TEM images. A standard sample made with ammonia (and APTMS) is also shown for comparison in black;

FIG. 4 illustrates an optoelectronic device with a matrix including encapsulated quantum dots derived by the method according to the proposed principle.

### DETAILED DESCRIPTION

The following embodiments and examples disclose various aspects and their combinations according to the proposed principle. The embodiments and examples are not always to scale. Likewise, different elements can be displayed enlarged or reduced in size to emphasize individual aspects. It goes without saying that the individual aspects of the embodiments and examples shown in the figures can be combined with each other without further ado, without this contradicting the principle according to the invention. Some aspects show a regular structure or form. It should be noted that in practice slight differences and deviations from the ideal form may occur without, however, contradicting the inventive idea.

The present invention concerns among other aspects an amine-free method for the production of silica encapsulated quantum dots with improved photoluminescence quantum yield at elevated temperatures. A main advantage of the invention is that the reaction of the silica growth can be performed without the use of Ammonia and (3-Aminopropyl) trimethoxysilane (APTMS) as reactants.

Uses of quantum dot compositions having high PLOYs at high temperature are also disclosed, including solid state lighting. It is to be understood that the term “quantum dot” can be used to represent a variety of geometries such as, but not limited to, rods, spheres, or tetrapods, as well as asymmetric variations thereof.

In silica shelling reactions that would otherwise use NH3 (aq.) to catalyse the TEOS conversion to silica, LiOH (aq.) can be directly substituted as the base catalyst. Using LiOH (aq.) in place of NH3 (aq.) does not require APTMS to synthesize high-quality silica spheres. Each quantum dot is individually encapsulated, and the thickness of the silica shell can be tuned by changing the concentration of LiOH (aq.) as well as growth temperature and growth time.

Because to the different base catalyst, it has been found that voids at the QD surface are eliminated. In other words the proposed new base catalyst causes a more uniform and thus complete silica growth around the quantum dots. While the sphere's surface appears slightly rougher in TEM images than the traditional synthesis route with NH3 (aq.), the thickness of the silica layer can be varied by changing the LiOH (aq.) concentration.

As APTMS is not used for this growth process less carbon is introduced into the system, which is important for long term reliability testing at elevated temperatures.

In general, an amine-free route to obtain silica-encapsulated quantum dots is advantageous and desirable, as there can be seen negative impacts on photoluminescent quantum yield (PLQY) when quantum dots are mixed with NH3 (aq.) prior to encapsulation.

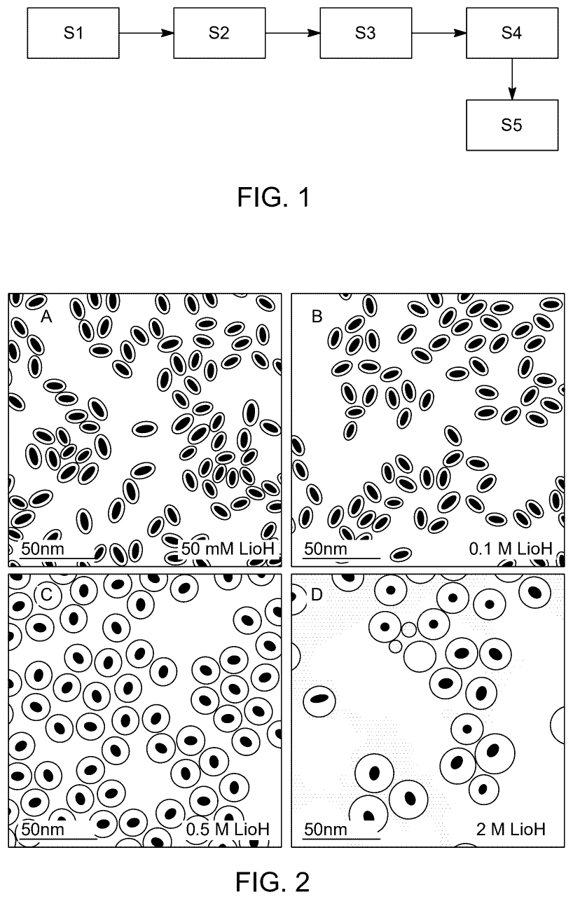

FIG. 1 illustrates a method for the production of a luminescent material based on silica encapsulated quantum dots in accordance with some aspects of the proposed principle.

In step S1, the luminescent quantum dots are provided in a liquid medium suitable to facilitate the reaction. In some examples, a solvent is used, in which the QDs are also dispersed in after synthesis. This solvent is usually a non-polar solvent like cyclohexane, If needed the solution of quantum dots in the liquid are slightly shaken or stirred to achieve uniformity during the subsequent process steps.

In a second step S2, silica precursors such as TEOS, TMOS and the like and Li(OH) for example is added to the liquid medium. For this purpose, TEOS may be added first and the stirred into the liquid to provide good uniformity of TEOS. To initiate the growth process the Li(OH) is added in the right concentration. Li(OH) may be added as solid or as a liquid. Preferably Li(OH) is pre-dissolved in water or alcohol to generate the desired concentration and then added to the mixture. The encapsulation process of the quantum dots is catalysed by the Li(OH) but may also be supported by proper temperature setting. Consequently, in some instance the components may be mixed together at a first temperature, which is then subsequently changed to a second temperature to facilitate the encapsulation process.

In an alternative embodiment, TEOS and Li(OH) are prepared separately prior to adding the mixture to the liquid. This is done in such a way as to avoid the chemical process of changing TEOS to silica, e.g. directly prior to adding the mixture to the liquid. In some instances, the concentration of Li(OH) can be increased or decreased to facilitate the growth of silica around the quantum dots. Due to the use of Li(OH), one can avoid the presence of NH3 or other amines adjacent to the surface of the quantum dots, and a reduction of the PLQY is minimized or even avoided.

In step S3, the growth is initiated until a small and uniform shell is form encapsulating the quantum dots fully. The growth process can continue until the desired thickness is reached. In this regard one may change the concentration of the hydroxyl base or methoxide base substance, add or even replace the substance with a different hydroxyl base. For example, one may add K(OH) or Ca(OH)₂ or a methoxide base to the Li(OH) containing liquid to further facilitate the encapsulation process until the desired thickness is reached.

In an alternative embodiment depicted herein in FIG. 1, the growth process is varied by adding NH3 into the liquid in Step S4 after the initial growth and encapsulation. Adding NH3 adding at this stage avoid the creation of voids, because the initial growth in step S3 using Li(OH) or another hydroxyl base or methoxide base already provided a full encapsulation of the quantum dots. Rather, the growth of the shell encapsulating the quantum dots is continued in step S5 until the desired thickness is reached.

Steps S4 an S5 can be amended or repeated with different catalyst. Further, additional TEOS may be added if needed to avoid a shift of the equilibrium reaction of TEOS into silica.

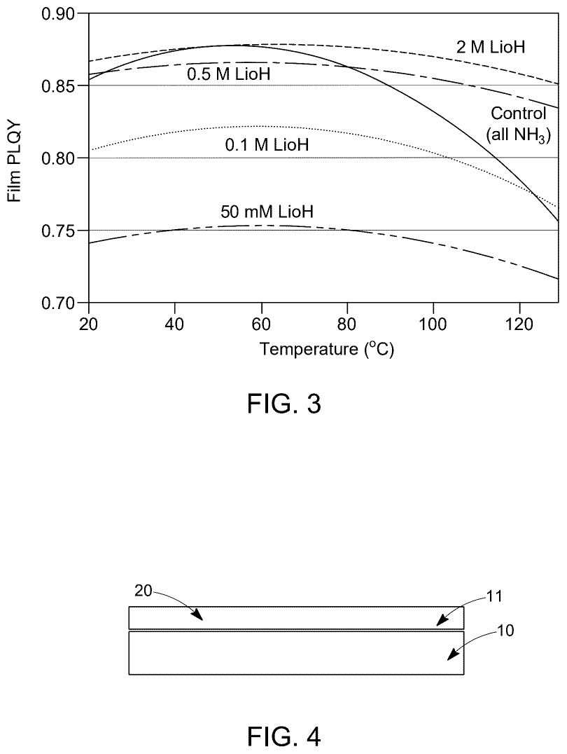

FIGS. 2A to 2D illustrate the growth of silica on the surface of quantum dots as facilitated by different concentrations of Li(OH) for a given time. Each figure has the same scale to make the result directly comparable. The encapsulation process was conducted at different concentrations for added Li(OH), in particular 0.05 M in FIG. 2A, 0.1 M for FIG. 2B, 0.5M for FIG. 3B and 2 M for FIG. 2D. the quantum dots to be encapsulated have a rectangular brick or cylinder like shape. The average length of the quantum dots is in the range of about 7 nm to 15 nm.

As shown in FIG. 2A at low concentrations the encapsulation process takes a significant longer time and generates a less uniforms and smooth shell. Thickness of the silica on the different quantum dots may vary as well resulting in a higher standard deviation for the overall size of the encapsulated quantum dots. The average size of the encapsulated quantum dots is in the range between 15 nm to 25 nm in length, but the lengthy shape remains. Hence, the encapsulation quantum dots do not form small balls but have a rather brick like shape resembling those of the original quantum dots.

The uniformity of the shell increases when increasing the concentration of the catalyst from 0.05 M to 0.5 M as shown in FIG. 2C. While in FIG. 2B, the overall shape of the encapsulated quantum dots still resembles an elongated shape, the encapsulated quantum dots form balls with a circular shape due to the picture. The encapsulated quantum dots comprise a uniform size in the range of 20 nm to 30 nm. The standard deviation in respect to its size decreases and is in particular lower than in the previous FIGS. 2A and 2B.

With larger concentration of added catalyst, the size of the encapsulated quantum dots increases further. However, if the concentration is larger than about 3 M, additional growth of TEOS takes place not encapsulating the quantum dots. The reason for such behaviour may be cause by a self-induced growth due to the concentration of the base, which is high enough to no longer be required to rely on the quantum dots as seed. This is partially already observed in FIG. 2D, whereas the surface of the shell can act as such seed resulting in a less smooth surface and less uniform growth. Hence, very large concentration seems to affect the uniform shape and may also led to a higher standard deviation of the shell size. The average size of the shells encapsulating quantum dots in FIG. 2D is in the range of 20 nm to 38 nm.

In summary, silica shells that are grown using [LiOH]≥0.5 M in accordance with the proposed principle result in improved performance in temperature-dependent growth over samples synthesized via the standard procedure, with NH3.

In some aspects of the proposed principle LiOH(s) is weighed out and suspended in H2O (l) to achieve the desired LiOH (aq.) concentration. APTMS is not added to the reaction, and LiOH (aq.) is substituted for NH3 (aq.) in an equivalent volume (for total sample volume consistency).

FIG. 3 shows PLQY data as a function of temperature for films made from the LiOH samples presented in the FIG. 2 with TEM images. A standard sample synthesized using ammonia and APTMS is also shown for comparison in black. The trend of increasing PLQY values at every temperature as [LiOH] increases is clear, combined with a “flattening” of the curve at higher temperatures. This behaviour results in equal or greater PLQY response at elevated temperatures for samples where [LiOH]≥0.1 M when compared to the standard sample. This is particularly useful at concentrations above 0.5 M, whereas the PLQY is larger for a temperature range between room temperature (of 24° C.) and 90° C. compared to the PLQY of quantum dots generated with conventional techniques.

FIG. 4 shows an exemplary embodiment of an optoelectronic device with a matrix comprising the encapsulated quantum dots in accordance with some aspects of the proposed principle.

The optoelectronic device includes a semiconductor body 10 (e.g. an LED) having an active region between two differently doped current transportation layers. The active layer in semiconductor body 10 is configured to emit light in operation of the device, whereas a wavelength of the emitted light is shorter than the emission wavelength of the quantum dots. The light of the semiconductor body 10 is emitted mainly through surface 11 on which a matrix 20 is attached to. Surface 11 can be roughened or otherwise treated to increase emission efficiency and ensure that the light emitted from the surface is coupling into matrix 20.

Matrix 20 comprises a transparent component that includes the encapsulated quantum dots embedded therein. The refractive index of the transparent component is preferably close to the refractive index of the silica material of the quantum dots to avoid refraction or reflection. During operation light emitted from the active region of body 10 will emit through surface 11 and be absorbed by quantum dots within the matrix 20. As mentioned, the energy of the emitted photons is large than the bandgap of the quantum dots, so that the photons are absorbed by the quantum dots and then reemitted by them, thus converting the emitted photons to photons of a longer wavelength. Depending on the concentration of the quantum dots in matrix 20 and/or the thickness of matrix 20 a full wavelength conversion can be reached, that is all emitted photons ae converted by the encapsulated quantum dots. Alternatively white light can be generated by only converting a portion of the emitted photons i.e. by reducing thickness of matrix 20 or reducing concentration of quantum dots within matrix 20.

REFERENCE LIST

| | |
|---|---|
| 10 | semiconductor body (LED) |
| 11 | emission surface |
| 20 | matrix with embedded encapsulated quantum dots |

1.-12. (canceled)

13. A method for production of a luminescent material based on silica encapsulated quantum dots, comprising:
providing luminescent quantum dots in a liquid medium;
adding one of Tetraethyl orthosilicate (TEOS) and Tetramethyl orthosilicate (TMOS) and a hydroxyl base or methoxide base to the liquid medium; and
growing silica on the luminescent quantum dots, thereby obtaining the silica encapsulated quantum dots;
wherein the method is free of Ammonia and (3-Aminopropyl)trimethoxysilane (APTMS) as reactants.

14. The method according to claim 13, wherein the quantum dots comprise an elongated shape optionally with a length between 5 nm and 20 nm or between 7 nm and 15 nm.

15. The method according to claim 13, wherein the hydroxyl base is selected from LiOH, NaOH, KOH, RbOH, CsOH, Mg(OH)₂, Ca(OH)₂, Sr(OH)₂, Ba(OH)₂ or Zn(OH)₂, or mixtures thereof.

16. The method according to claim 13, wherein the methoxide base is selected from Lithium methoxide, Sodium methoxide, Potassium methoxide, or mixtures thereof.

17. The method according to claim 13, wherein the liquid medium is selected from water, methanol, or ethanol.

18. The method according to claim 13, wherein a concentration of the hydroxyl base or the methoxide base is between 0.05 M and 3.0 M; or
wherein the hydroxyl base or methoxide base corresponds to a concentration of 0.025 M of a base in a total reaction volume.

19. The method according to claim 13, wherein a combination of the hydroxyl base and ammonia is used.

20. The method according to claim 19, wherein a combination of M(OH)n(aq.) and NH3(aq.) is used, with (M(OH)n)1−x((NH3)x(aq,), wherein n=1 or 2, 0≤x≤1 and M is Li, Na, K, Rb, Cs for n=1 and Mg, Ca, Sr, Ba or Zn for n=2.

21. The method according to claim 13, wherein after the growing of the silica on the luminescent quantum dots is performed, adding ammonia and repeating one or more times the growing of the silica on the luminescent quantum dots.

22. Silica encapsulated quantum dots prepared by the method according to claim 13.

23. An optoelectronic device comprising a light emission surface and a plurality of the silica encapsulated quantum dots of claim 21 arranged above the light emission surface.
